(19) United States
(12) Patent Application Publication
(10) Pub. No.: US 2026/0123186 A1
(43) Pub. Date: Apr. 30, 2026

(54) DISPLAY PANEL AND DISPLAY DEVICE

(71) Applicant: Wuhan Tianma Microelectronics Co., Ltd. Shanghai Branch, Shanghai (CN)

(72) Inventors: Huiping CHAI, Shanghai (CN); Xian CHEN, Shanghai (CN)

(73) Assignee: Wuhan Tianma Microelectronics Co., Ltd. Shanghai Branch, Shanghai (CN)

(21) Appl. No.: 19/061,947

(22) Filed: Feb. 24, 2025

(30) Foreign Application Priority Data
Oct. 29, 2024 (CN) 202411526277.8

(51) Int. Cl. H10K 59/122; H10K 59/131

(52) U.S. Cl. CPC H10K 59/122; H10K 59/131

(57) ABSTRACT

The present application relates to a display panel including: a substrate; a first metal layer located on a side of the substrate and including first metal patterns; first electrodes and a pixel definition layer. An outer contour of an orthographic projection of the first electrode is located outside that of the corresponding first pixel opening; an overlapped part of an orthographic projection of the first metal pattern and the first pixel opening is a first overlapped projection; part of the first metal pattern corresponding to the first overlapped projection is an overlapped part comprising a first side wall facing direction A1 and a second side wall facing direction A2 opposite and parallel to direction A1; a ratio of length component of the first to the second side wall along direction B1 intersecting with direction A1 is greater than or equal to 0.3 and less than or equal to 3.

### CROSS-REFERENCE TO RELATED APPLICATION

This application claims priority to Chinese patent application No. 202411526277.8, entitled “DISPLAY PANEL AND DISPLAY DEVICE”, filed on Oct. 29, 2024, the entire contents of which are incorporated here by reference.

### TECHNICAL FIELD

The present application relates to the field of display technology, and particularly, to a display panel and a display device.

### BACKGROUND

With the progress in science and technology, smart phones, tablet computers and other digital display devices are widely used, and display screens are indispensable interpersonal communication interfaces in these digital display devices. For example, an organic light emitting diode (OLED) display panel has advantages of self-luminescence, energy-saving and consumption reduction, bendability, flexibility, and the like. Such display device for displaying does not need back light and has characteristics of a fast response and a desired display effect. It has attracted the attention of users, and is widely used in smart phones, tablet computers and other terminal products. However, differences in color casts of current display panels are relatively big under the large viewing angles, which affects display effects.

### SUMMARY

Based on this, it is necessary to provide a display panel and a display device in order to improve display effects.

In a first aspect, embodiments of the present application provide a display panel including a substrate, a first metal layer, a first electrode, and a pixel definition layer.

The first metal layer is located on a side of the substrate and includes a first metal pattern; the first electrode is located on a side of the substrate; the pixel definition layer is located on a side of the first electrode away from the substrate and includes a first pixel opening corresponding to the first electrode; and an outer contour of an orthographic projection of the first electrode on the substrate is located outside of an outer contour of an orthographic projection of the corresponding first pixel opening on the substrate;
an overlapped part of an orthographic projection of the first metal pattern on the substrate and the orthographic projection of the first pixel opening on the substrate is a first overlapped projection; a part of the first metal pattern corresponding to the first overlapped projection is an overlapped part; the overlapped part includes a first side wall facing a direction A1 and a second side wall facing a direction A2 opposite and parallel to the direction A1;
a ratio of a length component of the first side wall along a direction B1 intersecting with the direction A1 to a length component of the second side wall along a direction B1 is greater than or equal to 0.3 and less than or equal to 3.

In a second aspect, embodiments of the present application provide a display device including the display panel including a substrate, a first metal layer, a first electrode, and a pixel definition layer.

The first metal layer is located on a side of the substrate and includes a first metal pattern; the first electrode is located on a side of the substrate; the pixel definition layer is located on a side of the first electrode away from the substrate and includes a first pixel opening corresponding to the first electrode; and an outer contour of an orthographic projection of the first electrode on the substrate is located outside of an outer contour of an orthographic projection of the corresponding first pixel opening on the substrate;
an overlapped part of an orthographic projection of the first metal pattern on the substrate and the orthographic projection of the first pixel opening on the substrate is a first overlapped projection; a part of the first metal pattern corresponding to the first overlapped projection is an overlapped part; the overlapped part includes a first side wall facing a direction A1 and a second side wall facing a direction A2 opposite and parallel to the direction A1;
a ratio of a length component of the first side wall along a direction B1 intersecting with the direction A1 to a length component of the second side wall along a direction B1 is greater than or equal to 0.3 and less than or equal to 3.

### BRIEF DESCRIPTION OF THE DRAWINGS

In order to illustrate technical solutions in embodiments or exemplary embodiments of the present application more clearly, the drawings to be used in the description of the embodiments or the exemplary embodiments of will be briefly introduced below. It is obvious that the drawings described below are merely some embodiments of the present application, and for those of ordinary skill in the art, other drawings may be obtained based on these drawings without inventive effort.

FIG. 1 is a schematic view observed by human eyes under a convex model according to an embodiment of the present application.

FIG. 2 is a schematic view observed by human eyes under a concave model according to an embodiment of the present application.

FIG. 3 is a schematic cross-sectional structural view of a display panel in a first orientation according to an embodiment of the present application.

FIG. 4 is a partial schematic plan view of a first metal layer in an embodiment of the present application.

FIG. 5 is schematic projection views of a first metal layer and a first pixel opening shown in FIG. 4.

FIG. 6 is a schematic cross-sectional structural view of a display panel in a second orientation according to an embodiment of the present application.

FIG. 7 is schematic projection views of a first metal pattern and a first sub-pixel opening shown in the schematic projection view shown in FIG. 5.

FIG. 8 is a partial schematic structural view corresponding to section E-E in FIG. 7.

FIG. 9 is schematic projection views of a first metal pattern and a second sub-pixel opening shown in the schematic projection view shown in FIG. 5.

FIG. 10 is a partial schematic structural view corresponding to section F-F in FIG. 9.

FIG. 11 is schematic projection views of a first metal pattern and a third sub-pixel opening shown in the schematic projection view shown in FIG. 5.

FIG. 12 is a partial schematic structural view corresponding to section G-G in FIG. 11.

FIG. 13 is a partial schematic cross-sectional structural view of another display panel according to an embodiment of the present application.

FIG. 14 is a partial schematic cross-sectional structural view of yet another display panel according to an embodiment of the present application.

FIG. 15 is a schematic structural view of a display device according to an embodiment of the present application.

### REFERENCE NUMERALS

100: Display device; 10: Display panel; 11: Substrate; 12: First metal layer; 121: First metal pattern; 121a: Overlapped part; 121al: First overlapped part; 121a2: Second overlapped part; 121a3: Third overlapped part; 121a-1: First side wall; 121a-1-1: First sub-wall; 121a-1-2: Second sub-wall; 121a-1-3: Third sub-wall; 121a-1-4: Fourth sub-wall; 121a-1-5: Seventh sub-wall; 121a-1-6: Eighth sub-wall; 121a-1-7: Ninth sub-wall; 121a-2: Second side wall; 121a-2-1: Fifth sub-wall; 121a-2-2: Sixth sub-wall; 121a-2-3: Tenth sub-wall; 121a-2-4: Eleventh sub-wall; 121a-2-5: Twelfth sub-wall; 121a-3: Third side wall; 121a-3-1: Thirteenth sub-wall; 121a-3-2: Fourteenth sub-wall; 121a-3-3: Fifteenth sub-wall; 121a-3-4: Sixteenth sub-wall; 121a-4: Fourth side wall; 121a-4-1: Seventeenth sub-wall; 121a-4-2: Eighteenth sub-wall; 121a-4-3: Nineteenth sub-wall; 121a-4-4: Twentieth sub-wall; 1211: First sub-pattern; 1212: Second sub-pattern; 1213: Third sub-pattern; 13: First electrode; 14: Pixel definition layer; 14a: First pixel opening; 14a1: First sub-pixel opening; 14a2: Second sub-pixel opening; 14a3: Third sub-pixel opening; 15: First insulation layer; 16: Semiconductor layer; 17: Second insulation layer; 18: Second metal layer; 19: Third insulation layer; 110: Third metal layer; 111: Fourth insulation layer; 112: Fifth insulation layer; 113: Oxide metal layer; 114: Sixth insulation layer; 115: Fourth metal layer; 116: Seventh insulation layer; 117: Fifth metal layer; 118: First planarization layer; 119: Support column; S1: First overlapped projection; Sla: First sub-overlapped projection; S1b: Second sub-overlapped projection; S1c: Third sub-overlapped projection.

### DETAILED DESCRIPTION

The present application will be described more thoroughly with reference to the drawings below to facilitate the understanding thereof. Preferred embodiments of the present application are provided in the drawings. However, the present application may be embodied in many different forms and is not limited to the embodiments described herein. Rather, these embodiments are provided for more thorough and complete understanding of content disclosed in the present application.

Unless otherwise defined, all technical and scientific terms used herein has the same meaning commonly understood by a person skilled in the art of the present application. Terms used in the specification of the present application are for describing specific embodiments only and are not intended to limit the present application. The term “and/or” used herein includes any and all combinations of one or more related listed items.

Under a condition that positional relationships are described, unless stated otherwise, when one element such as a layer, film or substrate is referred to as being “on” the other element, it may be directly on the other element or intervening elements may be provided therebetween. Further, when one layer is referred to as being “under” the other layer, it may be directly under the other layer or intervening elements may be provided therebetween. It may also be understood that when one layer is referred to as being “between” two layers, it may be the only layer between the two layers or intervening elements may be provided therebetween.

Under a condition that the terms “comprising”, “having”, and “including” described herein are used, another component may be added unless an explicit limitation such as “only”, “consisting of” is used. The terms of singular forms may include plural forms unless the context clearly dictates otherwise.

It should be understood that, although the terms such as “first”, “second” may be used herein to describe various elements, these elements should not be limited by these terms. These terms are only used for distinguishing one element from another. For example, a first element may be referred to as a second element, and similarly, a second element may be referred to as a first element, without departing from the scope of the present application.

It should also be understood that, when an element is explained, although not explicitly described, the element is explained as including error ranges which are within acceptable deviation ranges of specific values determined by a person skilled in the art. For example, “about”, “approximately”, or “substantially” may mean the error ranges are within one or more standard deviations, which is not limited here.

Further, in the specification, the phrase “plane distribution schematic view” refers to a drawing when a target part is observed from above, and the phrase “cross-sectional schematic view” refers to a drawing when a cross-section taken by vertically cutting the target part is observed from a side.

Further, the drawings are not drawn to actual scale, and relative sizes of various elements are drawn in the drawings by way of an example only and not necessarily to true scale.

With the progress in science and technology, smart phones, tablet computers and other digital display devices are widely used, and display screens are indispensable interpersonal communication interfaces in these digital display devices. For example, an organic light emitting diode (OLED) display panel has advantages of self-luminescence, energy-saving and consumption reduction, bendability, flexibility, and the like. Such display device for displaying does not need back light and has characteristics of a fast response and a desired display effect. It has attracted the attention of users and is widely used in smart phones, tablet computers, and other terminal products. However, differences in color cast of current display panels are relatively serious under large viewing angles, which affects display effects. Specifically, taking for example the plane viewing angle of the display panel, there are four directions, i.e., an upper side direction, a lower side direction, a left side direction and a right side direction, with respect to the display panel; the difference in color cast between the upper side and the lower side is relatively serious under a condition that an observer observes from the upper side or the lower side, and also the difference in color cast between the left side and the right side is relatively serious under a condition that the observer observes from the left side or the right side. The above phenomenon seriously affects the display effects.

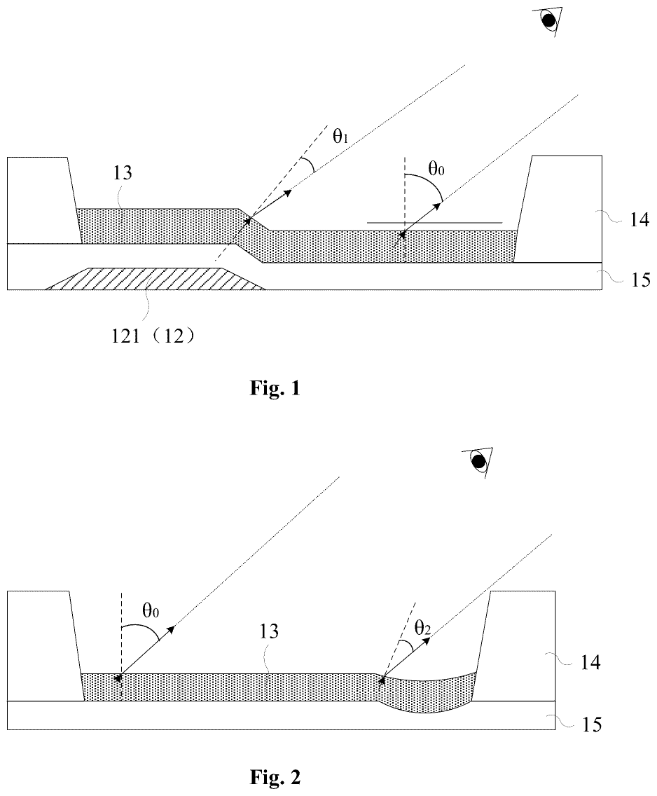

The inventor has found that, with reference to FIG. 1, under a convex model, that is, under a condition that a first electrode (anode) has a protrusion, when human eyes observe from a large viewing angle, an incident angle θ1 at the protrusion is less than an incident angle θ0 at a horizontal level, and changes in resonance conditions cause the difference in the color casts. Specifically, hues at the protrusion are different from that at the horizontal level, and luminance attenuation at the protrusion is different from that at the horizontal level. With reference to FIG. 2, under a concave model, that is, under a condition that the first electrode (anode) has a depression, when the human eye observes under the large viewing angle, an incident angle θ2 at the depression is less than the incident angle θ0 at the horizontal level, and changes in the resonance conditions cause the difference in color cast. Specifically, hues at the depression are different from that at the horizontal level, and luminance attenuation at the depression is different from that at the horizontal level. In a word, the inventor has found that steps at the protrusions or the depressions are main causes of the color casts.

In view of this, embodiments of the present application provide a display panel and a display device, a ratio of a length component of a first side wall along a direction B1 of an overlapped part of a first metal pattern and a first pixel opening along a direction A1 to a length component of a second side wall along the direction B1 of an overlapped part of the first metal pattern and the first pixel opening along the direction A2 is greater than or equal to 0.3 and less than or equal to 3, so that a difference in magnitude of the length components of the first side wall and the second side wall along the direction B1 is not very big, and under a condition that the observer observes from the right side (corresponding to the direction A1) or from the left side (corresponding to the direction A2) under the large viewing angle, the difference in the color casts of the left side and the right side is not very big, thereby improving the display effect.

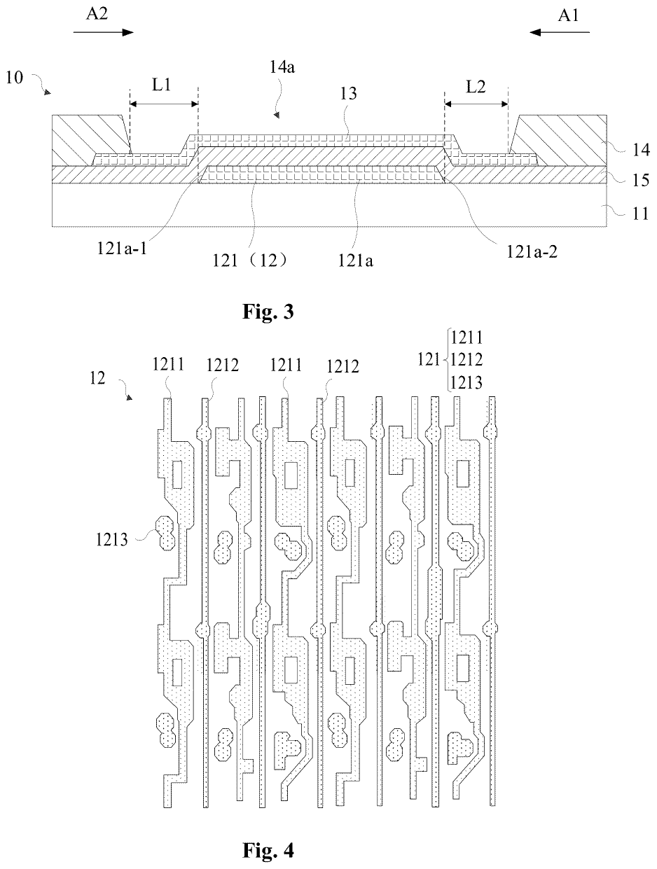

In a first aspect, with reference to FIGS. 3 to 5, embodiments of the present application provide a display panel 10, which may be an organic light emitting diode (OLED) display or a quantum dot light emitting diode (QLED) display.

Specifically, the display panel 10 includes a substrate 11, a first metal layer 12, a first electrode 13, and a pixel definition layer 14. The first metal layer 12 is located on a side of the substrate 11 and includes a first metal pattern 121. The first electrode 13 is located on a side of the substrate 11, and there are a plurality of first electrodes 13 arranged at intervals on a same side of the substrate 11. The pixel definition layer 14 is located on a side of the first electrode 13 away from the substrate 11 and includes a first pixel opening 14a corresponding to the first electrode 13. Specifically, the pixel definition layer 14 includes a plurality of first pixel openings 14a that may be in a one-to-one correspondence with the plurality of first electrodes 13 above, each first pixel opening 14a exposes a part of a surface of the corresponding first electrode 13. An outer contour of an orthographic projection of the first electrode 13 on the substrate 11 is located an outside of an outer contour of an orthographic projection of the corresponding first pixel opening 14a on the substrate 11.

An overlapped part of an orthographic projection of the first metal pattern 121 on the substrate 11 and the orthographic projection of the first pixel opening 14a on the substrate 11 is a first overlapped projection S1; a part of the first metal pattern 121 corresponding to the first overlapped projection S1 is an overlapped part 121a; the overlapped part 121a includes a first side wall 121a-1 facing a direction A1 and a second side wall 121a-2 facing a direction A2 opposite and parallel to the direction A1.

A ratio of a length component of the first side wall 121a-1 along the direction B1 to a length component of the second side wall 121a-2 along the direction B1 is greater than or equal to 0.3 and less than or equal to 3. The direction B1 intersects the direction A1. In FIG. 3, the direction B1 is perpendicular to the plane of the paper. In one preferred embodiment, the direction B1 is perpendicular to the direction A1.

It may be understood that the ratio of the length component of the first side wall 121a-1 along the direction B1 to the length component of the second side wall 121a-2 along the direction B1 may be 0.3, 0.5, 0.8, 1.2, 1.5, 1.8, 2.1, 2.3, 2.5, 2.7, 2.9, 3, or between any two of these values.

With reference to FIG. 3, the first side wall 121a-1 of the overlapped part 121a causes the first electrode 13 to have a step facing the direction A1, and the second side wall 121a-2 of the overlapped part 121a causes the first electrode 13 to have a step facing the direction A2. In the embodiments of the present application, the ratio of the length component of the first side wall 121a-1 along the direction B1 to the length component of the second side wall 121a-2 along the direction B1 is greater than or equal to 0.3 and less than or equal to 3, which means that a difference in magnitude of the length components of the first side wall 121a-1 and the second side wall 121a-2 along the direction B1 is not very big, that is, a difference in a length of a step of the first electrode 13 facing the direction A1 and a length of a step of the first electrode 13 facing the direction A2 is not very big, so that under a condition that an observer observes from the right side (corresponding to the direction A1) or from the left side (corresponding to the direction A2) under the large viewing angle, the difference in the color casts of the left side and the right side is not very big, thereby improving the display effect.

In one of the embodiments, the ratio of the length component of the first side wall 121a-1 along the direction B1 to the length component of the second side wall 121a-2 along the direction B1 is greater than or equal to 0.8 and less than or equal to 1.2.

In this way, the difference in the magnitude of the length components of the first side wall 121a-1 and the second side wall 121a-2 along the direction B1 is further reduced, and the difference in the length of the step of the first electrode 13 facing the direction A1 and the length of the step of the first electrode 13 facing the direction A2 is further reduced, so that under a condition that the observer observes from the right side (corresponding to the direction A1) or from the left side (corresponding to the direction A2) under the large viewing angle, the difference in the color casts of the left side and the right side is further reduced, thereby further improving the display effect.

In one of the embodiments, the length component of the first side wall 121a-1 along the direction B1 is equal to the length component of the second side wall 121a-2 along the direction B1. “Equal” may mean “absolutely equal” or “approximately equal” herein. Under a condition that the ratio of the length component of the first side wall 121a-1 along the direction B1 to the length component of the second side wall 121a-2 along the direction B1 is equal to 1, the length component of the first side wall 121a-1 along the direction B1 is absolutely equal to the length component of the second side wall 121a-2 along the direction B1; under a condition that the ratio of the length component of the first side wall 121a-1 along the direction B1 to the length component of the second side wall 121a-2 along the direction B1 is greater than or equal to 0.95 and less than or equal to 1.05, the length component of the first side wall 121a-1 along the direction B1 is approximately equal to the length component of the second side wall 121a-2 along the direction B1.

In this way, the length component of the first side wall 121a-1 along the direction B1 is close to the length component of the second side wall 121a-2 along the direction B1 as much as possible, and the length of the step of the first electrode 13 facing the direction A1 is close to the length of the step of the first electrode 13 facing the direction A2 as much as possible, so that under a condition that the observer observes from the right side (corresponding to the direction A1) or from the left side (corresponding to the direction A2) under the large viewing angle, the difference in the color casts of the left side and the right side is very small (or there is almost no difference in the color casts of the left side and the right side), thereby further improving the display effect.

In one of the embodiments, as shown in FIG. 3, in the overlapped part 121a and the first pixel opening 14a corresponding to the overlapped part 121a, a distance between the first side wall 121a-1 of the overlapped part 121a and an edge of a side of the first pixel opening 14a close to the first side wall 121a-1 is L1, and L1 is greater than 0 μm. In the overlapped part 121a and the first pixel opening 14a corresponding to the overlapped part 121, a distance between the second side wall 121a-2 of the overlapped part 121a and an edge of a side of the first pixel opening 14a close to the second side wall 121a-2 is L2, and L2 is greater than 0 μm. In an example, L1 may be any value greater than 0 μm, such as 0.1 μm, 0.5 μm, 0.9 μm, 1.2 μm, 1.5 μm, 2 μm, and 3 μm. L2 may be any value greater than 0 μm, such as 0.1 μm, 0.5 μm, 0.9 μm, 1.2 μm, 1.5 μm, 2 μm, and 3 μm.

In this way, under a condition that the human eye observes from the left side and the right side in FIG. 3, both a step above the first side wall 121a-1 and a step above the second side wall 121a-2 may be observed by the human eye, so that the step on the left side and the step on the right side that are observed by the human eye may be equalized, which is beneficial to reduce the difference in the color casts and improve the display effect.

In one of the embodiments, in the overlapped part 121a and the first pixel opening 14a corresponding to the overlapped part 121a, the distance between the first side wall 121a-1 of the overlapped part 121a and the edge of the side of the first pixel opening 14a close to the first side wall 121a-1 is greater than or equal to 1 μm, that is, L1≥1 μm. In the overlapped part 121a and the first pixel opening 14a corresponding to the overlapped part 121, the distance between the second side wall 121a-2 of the overlapped part 121a and the edge of the side of the first pixel opening 14a close to the second side wall 121a-2 is greater than or equal to 1 μm, that is, L2≥1 μm.

In this way, under a condition that the human eye observes from the left side and the right side in FIG. 3, both a step above the first side wall 121a-1 and a step above the second side wall 121a-2 may be observed by the human eyes, so that the step on the left side and the step on the right side that are observed by the human eye may be equalized, which is beneficial to reduce the difference in the color casts and improve the display effect. Further, it is beneficial for process personnel to control process errors and reduce difficulty in production.

In one of the embodiments, 0 μm≤L1≤1 μm, and 0 μm≤L2≤1 μm.

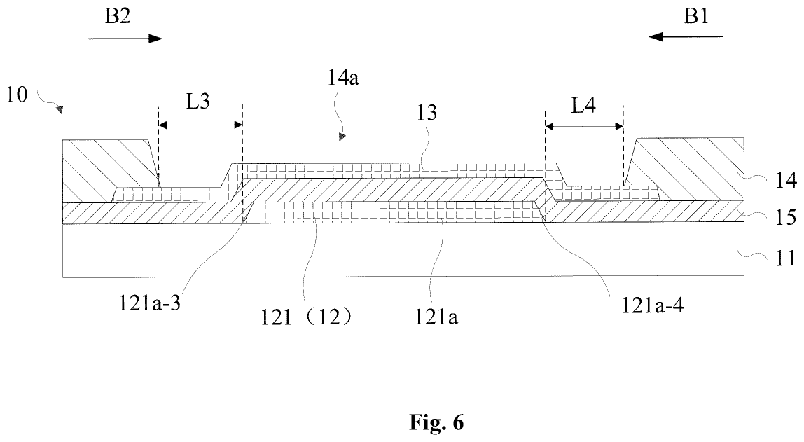

In one of the embodiments, as shown in FIG. 6, the overlapped part 121a includes a third side wall 121a-3 facing the direction B1 and a fourth side wall 121a-4 facing a direction B2; and orientations of the direction B1 and the direction B2 are opposite and parallel to each other. A ratio of a length component of the third side wall 121a-3 along the direction A1 to a length component of the fourth side wall 121a-4 along the direction A1 is greater than or equal to 0.3 and less than or equal to 3. In FIG. 6, the direction A1 is perpendicular to the plane of the paper.

It may be understood that the ratio of the length component of the third side wall 121a-3 along the direction A1 to the length component of the fourth side wall 121a-4 along the direction A1 may be 0.3, 0.5, 0.8, 1.2, 1.5, 1.8, 2.1, 2.3, 2.5, 2.7, 2.9, 3, or between any two of these values.

With reference to FIG. 6, the third side wall 121a-3 of the overlapped part 121a causes the first electrode 13 to have a step facing the direction B1, and the fourth side wall 121a-4 of the overlapped part 121a causes the first electrode 13 to have a step facing the direction B2. In the embodiments of the present application, the ratio of the length component of the third side wall 121a-3 along the direction A1 to the length component of the fourth side wall 121a-4 along the direction A1 is greater than or equal to 0.3 and less than or equal to 3, which means that a difference in magnitude of the length components of the third side wall 121a-3 and the fourth side wall 121a-4 along the direction A1 is not very big, that is, a difference in a length of a step of the first electrode 13 facing the direction B1 and a length of a step of the first electrode 13 facing the direction B2 is not very big, so that under a condition that the observer observes from the upper side (corresponding to the direction B1) or from the lower side (corresponding to the direction B2) under the large viewing angle, a difference in color casts of the upper side and the lower side is not very big, thereby improving the display effect.

In one of the embodiments, the ratio of the length component of the third side wall 121a-3 along the direction A1 to the length component of the fourth side wall 121a-4 along the direction A1 is greater than or equal to 0.8 and less than or equal to 1.2.

In this way, the difference in the magnitude of the length components of the third side wall 121a-3 and the fourth side wall 121a-4 along the direction A1 is further reduced, that is, the difference in the length of the step of the first electrode 13 facing the direction B1 and the length of the step of the first electrode 13 facing the direction B2 is further reduced, so that under a condition that the observer observes from the upper side (corresponding to the direction B1) or from the lower side (corresponding to the direction B2) under the large viewing angle, the difference in the color casts of the upper side and the lower side is further reduced, thereby further improving the display effect.

In one of the embodiments, the length component of the third side wall 121a-3 along the direction A1 is equal to the length component of the fourth side wall 121a-4 along the direction A1. “Equal” may mean “absolutely equal” or “approximately equal” herein. Under a condition that the ratio of the length component of the third side wall 121a-3 along the direction A1 to the length component of the fourth side wall 121a-4 along the direction A1 is equal to 1, the length component of the third side wall 121a-3 along the direction A1 is absolutely equal to the length component of the fourth side wall 121a-4 along the direction A1; under a condition that the ratio of the length component of the third side wall 121a-3 along the direction A1 to the length component of the fourth side wall 121a-4 along the direction A1 is greater than or equal to 0.95 and less than or equal to 1.05, the length component of the third side wall 121a-3 along the direction A1 is approximately equal to the length component of the fourth side wall 121a-4 along the direction A1.

In this way, the length component of the third side wall 121a-3 along the direction A1 is close to the length component of the fourth side wall 121a-4 along the direction B1 as much as possible, and the length of the step of the third electrode 13 facing the direction B1 is close to the length of the step of the first electrode 13 facing the direction B2 as much as possible, so that under a condition that the observer observes from the upper side (corresponding to the direction B1) or from the lower side (corresponding to the direction B2) under the large viewing angle, the difference in the color casts of the upper side and the lower side is very small (or there is almost no difference in the color casts of the upper side and the lower side), thereby further improving the display effect.

In one of the embodiments, as shown in FIG. 6, in the overlapped part 121a and the first pixel opening 14a corresponding to the overlapped part 121a, a distance between the third side wall 121a-3 of the overlapped part 121a and an edge of a side of the first pixel opening 14a close to the third side wall 121a-3 is L3, and L1 is greater than 0 μm. In the overlapped part 121a and the first pixel opening 14a corresponding to the overlapped part 121, a distance between the fourth side wall 121a-4 of the overlapped part 121a and an edge of a side of the first pixel opening 14a close to the fourth side wall 121a-4 is L4, and L4 is greater than 0 μm. In an example, L3 may be any value greater than 0 μm, such as 0.1 μm, 0.5 μm, 0.9 μm, 1.2 μm, 1.5 μm, 2 μm, and 3 μm. L4 may be any value greater than 0 μm, such as 0.1 μm, 0.5 μm, 0.9 μm, 1.2 μm, 1.5 μm, 2 μm, and 3 μm.

In this way, under a condition that the human eye observes from the upper side and the lower side in FIG. 6, both the step above the third side wall 121a-3 and the step above the fourth side wall 121a-4 may be observed by the human eye, so that the step on the upper side and the step on the lower side that are observed by the human eye may be equalized, which is beneficial to reduce the difference in the color casts and improve the display effect.

In one of the embodiments, in the overlapped part 121a and the first pixel opening 14a corresponding to the overlapped part 121a, the distance between the third side wall 121a-3 of the overlapped part 121a and the edge of the side of the first pixel opening 14a close to the third side wall 121a-3 is greater than or equal to 1 μm, that is, L3≥1 μm. In the overlapped part 121a and the first pixel opening 14a corresponding to the overlapped part 121, the distance between the fourth side wall 121a-4 of the overlapped part 121a and the edge of the side of the first pixel opening 14a close to the fourth side wall 121a-4 is greater than or equal to 1 μm, that is, L4≥1 μm.

In this way, under a condition that the human eye observes from the upper side and the lower side in FIG. 6, both the step above the third side wall 121a-3 and the step above the fourth side wall 121a-4 may be observed by the human eye, so that the step on the upper side and the step on the lower side that are observed by the human eye may be equalized, which is beneficial to reduce the difference in the color casts and improve the display effect. Further, it is beneficial for the process personnel to control the process errors and reduce the difficulty in production.

In one of the embodiments, 0 μm≤L3≤1 μm, and 0 μm≤L4≤1 μm.

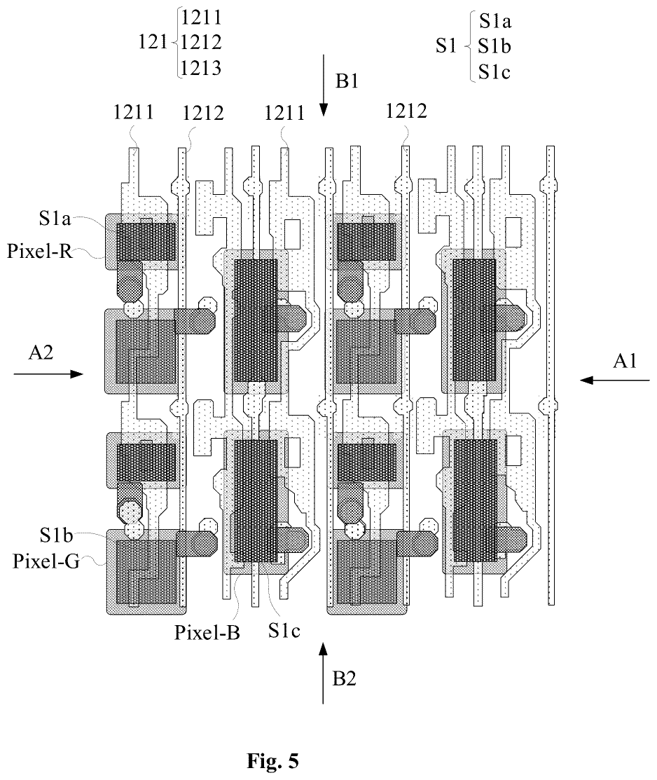

In one of the embodiments, as shown in FIG. 4 and FIG. 5, the first metal pattern 121 includes a plurality of first sub-patterns 1211 and a plurality of second sub-patterns 1212 which are arranged alternately, that is, a second sub-pattern 1212 is provided between any two adjacent first sub-patterns 1211, and a first sub-pattern 1211 is provided between any two adjacent second sub-patterns 1212. The first sub-pattern 1211 and the second sub-pattern 1212 are used for transmitting different electrical signals, respectively. An orthographic projection of at least one of the first sub-pattern 1211 or the second sub-pattern 1212 on the substrate 11 overlaps with an orthographic projection of the first pixel opening 14a on the substrate 11.

In this way, the designer may achieve a purpose of reducing the difference in the color casts by optimizing pattern appearances of the first metal pattern 121 (for example, the first sub-pattern 1211 and the second sub-pattern 1212) without changing a pixel arrangement.

In one of the embodiments, the first sub-pattern 1211 transmits a power signal (for example, a VDD power signal) and the second sub-pattern 1212 transmits a data signal.

In one of the embodiments, the first metal pattern 121 further includes a plurality of third sub-patterns 1213 that are in a one-to-one correspondence with the plurality of first electrodes 13 above, and each first electrode 13 is electrically connected to a corresponding wire of a pixel driving circuit of the corresponding third sub-pattern 1213.

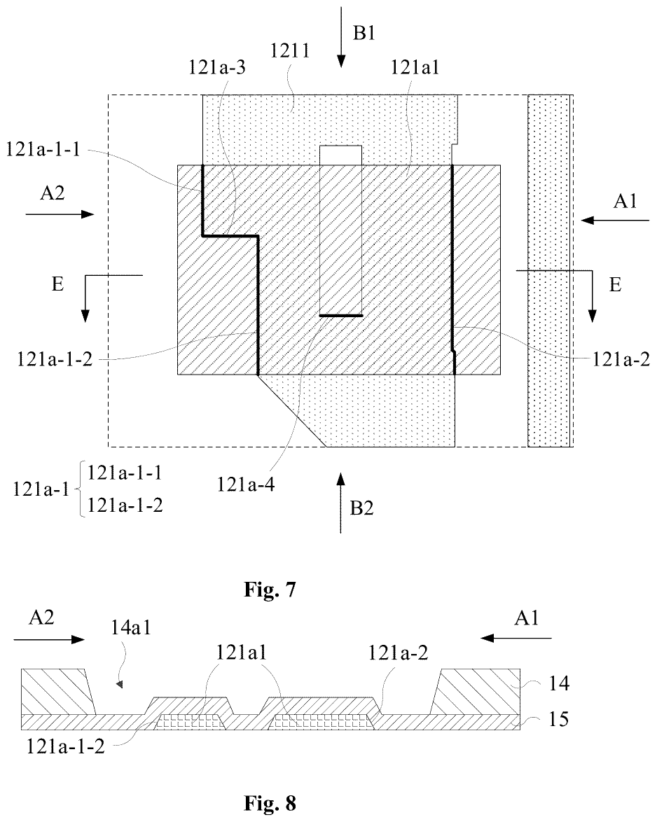

In one of the embodiments, as shown in FIG. 5, FIG. 7, and FIG. 8, the first pixel opening 14a includes a first sub-pixel opening 14a1. In an example, a pixel R corresponds to the first sub-pixel opening 14al.

Specifically, an orthographic projection of the first sub-pixel opening 14al on the substrate 11 overlaps with an orthographic projection of the corresponding first sub-pattern 1211 on the substrate 11, and the overlapped part is the first sub-overlapped projection Sla. For example in FIG. 5, the big shaded graph (rectangle) indicated by the line of the Pixel-R is equivalent to the orthographic projection of the first sub-pixel opening 14al, and the small shaded graph indicated by the line of Sla is the first sub-overlapped projection Sla. A part of the first sub-pattern 1211 corresponding to the first sub-overlapped projection Sla is a first overlapped part 121a1, the first side wall 121a-1 of the first overlapped part 121al includes a first sub-wall 121a-1-1 and a second sub-wall 121a-1-2 which are spaced apart from each other, and a sum of length components of the first sub-wall 121a-1-1 and the second sub-wall 121a-1-2 along the direction B1 is equal to the length component of the second side wall 121a-2 of the first overlapped part 121al along the direction B1.

Herein, side walls of the first overlapped part 121al along the direction A1 are not continuous (that is, spaced apart from each other), and are the first sub-wall 121a-1-1 and the second sub-wall 121a-1-2, respectively. In the embodiments of the present application, the arrangement of the first sub-wall 121a-1-1 and the second sub-wall 121a-1-2 is optimized, the sum of the length components of the first sub-wall 121a-1-1 and the second sub-wall 121a-1-2 along the direction B1 is equal to the length component of the second side wall 121a-2 of the first overlapped part 121al along the direction B1, and a total length of steps of the first electrodes 13 facing the direction A1 is close to a length of steps of the first electrodes 13 facing the direction A2 as much as possible, so that under a condition that the observer observes from the right side (corresponding to the direction A1) or from the left side (corresponding to the direction A2) under the large viewing angle, there is almost no difference in the color casts of the left side and the right side, thereby further improving the display effect.

It should be noted that, “equal” may mean “absolutely equal” or “approximately equal” herein. Under a condition that a ratio of the sum of the length components of the first sub-wall 121a-1-1 and the second sub-wall 121a-1-2 along the direction B1 to the length component of the second side wall 121a-2 of the first overlapped part 121al along the direction B1 is equal to 1, the sum of the length components of the first sub-wall 121a-1-1 and the second sub-wall 121a-1-2 along the direction B1 is absolutely equal to the length component of the second side wall 121a-2 of the first overlapped part 121al along the direction B1; under a condition that the ratio of the sum of the length components of the first sub-wall 121a-1-1 and the second sub-wall 121a-1-2 along the direction B1 to the length component of the second side wall 121a-2 of the first overlapped part 121al along the direction B1 is greater than or equal to 0.95 and less than or equal to 1.05, the sum of the length components of the first sub-wall 121a-1-1 and the second sub-wall 121a-1-2 along the direction B1 is approximately equal to the length component of the second side wall 121a-2 of the first overlapped part 121al along the direction B1.

It may be understood that the ratio of the sum of the length components of the first sub-wall 121a-1-1 and the second sub-wall 121a-1-2 along the direction B1 to the length component of the second side wall 121a-2 of the first overlapped part 121al along the direction B1 may also be greater than or equal to 0.8 and less than or equal to 1.2. The ratio of the sum of the length components of the first sub-wall 121a-1-1 and the second sub-wall 121a-1-2 along the direction B1 to the length component of the second side wall 121a-2 of the first overlapped part 121al along the direction B1 may also be greater than or equal to 0.3 and less than or equal to 3.

In one of the embodiments, a length component of the third side wall 121a-3 of the first overlapped part 121al along the direction A1 is equal to a length component of the fourth side wall 121a-4 of the first overlapped part 121al along the direction A1. One end of the third side wall 121a-3 is connected to the first sub-wall 121a-1-1, and the other end of the third side wall 121a-3 is connected to the second sub-wall 121a-1-2; and the fourth side wall 121a-4 is located between the second sub-wall 121a-1-2 and the second side wall 121a-2.

In this way, the designer achieves the purpose of reducing the difference in the color casts by optimizing pattern appearances of the first sub-patterns 1211 to reduce the difference in the color casts on the left side and the right side of the pixel R and the difference in the color casts on the upper side and the lower side of the pixel R without changing the pixel arrangement.

It may be understood that a ratio of the length component of the third side wall 121a-3 of the first overlapped part 121al along the direction A1 to the length component of the fourth side wall 121a-4 of the first overlapped part 121al along the direction A1 may be greater than or equal to 0.8 and less than or equal to 1.2. The ratio of the length component of the third side wall 121a-3 of the first overlapped part 121al along the direction A1 to the length component of the fourth side wall 121a-4 of the first overlapped part 121al along the direction A1 may also be greater than or equal to 0.3 and less than or equal to 3.

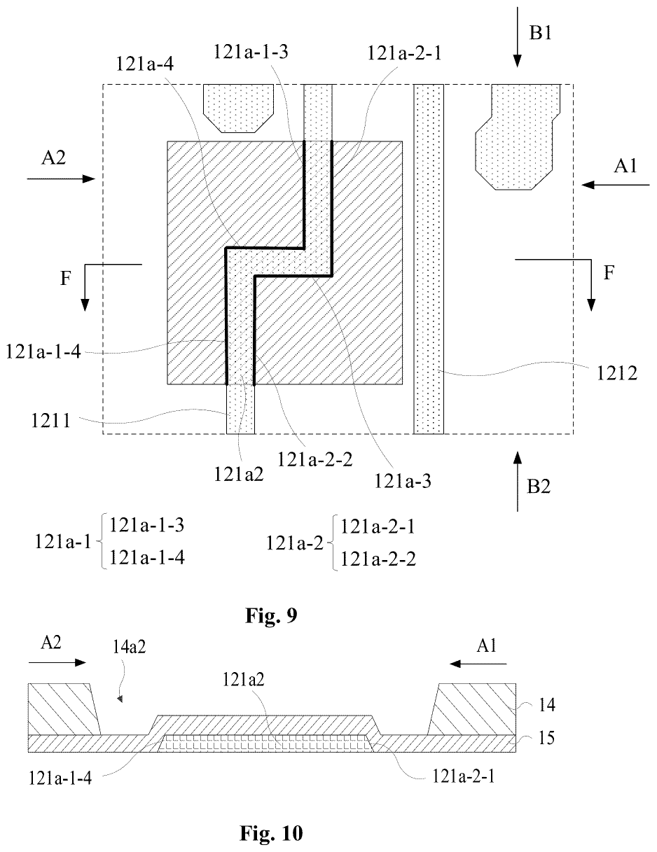

In one of the embodiments, as shown in FIG. 5, FIG. 9, and FIG. 10, the first pixel opening 14a includes a second sub-pixel opening 14a2. In an example, a pixel G corresponds to the second sub-pixel opening 14a2.

Specifically, an orthographic projection of the second sub-pixel opening 14a2 on the substrate 11 overlaps with an orthographic projection of the corresponding first sub-pattern 1211 on the substrate 11, and the overlapped part is the second sub-overlapped projection S1b. For example in FIG. 5, the big shaded pattern (rectangle) indicated by the line of the Pixel-G is equivalent to the orthographic projection of the second sub-pixel opening 14a2, and the small shaded graph indicated by the line of S1b is the second sub-overlapped projection S1b. A part of the first sub-pattern 1211 corresponding to the second sub-overlapped projection S1b is a second overlapped part 121a2, the first side wall 121a-1 of the second overlapped part 121a2 includes a third sub-wall 121a-1-3 and a fourth sub-wall 121a-1-4 which are spaced apart from each other, and the second side wall 121a-2 of the second overlapped part 121a2 includes a fifth sub-wall 121a-2-1 and a sixth sub-wall 121a-2-2 which are spaced apart from each other.

A sum of length components of the third sub-wall 121a-1-3 and the fourth sub-wall 121a-1-4 along the direction B1 is equal to a sum of length components of the fifth sub-wall 121a-2-1 and the sixth sub-wall 121a-2-2 along the direction B1.

Herein, side walls of the second overlapped part 121a2 facing the direction A1 are not continuous (that is, spaced apart from each other), and are the third sub-wall 121a-1-3 and the fourth sub-wall 121a-1-4, respectively, and side walls of the second overlapped part 121a2 facing the direction A2 are not continuous (that is, spaced apart from each other), and are the fifth sub-wall 121a-2-1 and the sixth sub-wall 121a-2-2, respectively. In the embodiments of the present application, the arrangement of the third sub-wall 121a-1-3, the fourth sub-wall 121a-1-4, the fifth sub-wall 121a-2-1, and the sixth sub-wall 121a-2-2 is optimized, the sum of the length components of the third sub-wall 121a-1-3 and the fourth sub-wall 121a-1-4 along the direction B1 is equal to the sum of the length components of the fifth sub-wall 121a-2-1 and the sixth sub-wall 121a-2-2 along the direction B1, and a total length of steps of the first electrodes 13 facing the direction A1 is close to a total length of steps of the first electrodes 13 facing the direction A2 as much as possible, so that under a condition that the observer observes from the right side (corresponding to the direction A1) or from the left side (corresponding to the direction A2) under the large viewing angle, there is almost no difference in the color casts of the left side and the right side, thereby further improving the display effect.

It should be noted that, “equal” may mean “absolutely equal” or “approximately equal” herein. Under a condition that the ratio of the sum of the length components of the third sub-wall 121a-1-3 and the fourth sub-wall 121a-1-4 along the direction B1 to the sum of the length components of the fifth sub-wall 121a-2-1 and the sixth sub-wall 121a-2-2 along the direction B1 is equal to 1, the sum of the length components of the third sub-wall 121a-1-3 and the fourth sub-wall 121a-1-4 along the direction B1 is absolutely equal to the sum of the length components of the fifth sub-wall 121a-2-1 and the sixth sub-wall 121a-2-2 along the direction B1; and under a condition that the ratio of the sum of the length components of the third sub-wall 121a-1-3 and the fourth sub-wall 121a-1-4 along the direction B1 to the sum of the length components of the fifth sub-wall 121a-2-1 and the sixth sub-wall 121a-2-2 along the direction B1 is greater than or equal to 0.95 and less than or equal to 1.05, the sum of the length components of the third sub-wall 121a-1-3 and the fourth sub-wall 121a-1-4 along the direction B1 is approximately equal to the sum of the length components of the fifth sub-wall 121a-2-1 and the sixth sub-wall 121a-2-2 along the direction B1.

It may be understood that the ratio of the sum of the length components of the third sub-wall 121a-1-3 and the fourth sub-wall 121a-1-4 along the direction B1 to the sum of the length components of the fifth sub-wall 121a-2-1 and the sixth sub-wall 121a-2-2 along the direction B1 may also be greater than or equal to 0.8 and less than or equal to 1.2. The ratio of the sum of the length components of the third sub-wall 121a-1-3 and the fourth sub-wall 121a-1-4 along the direction B1 to the sum of the length components of the fifth sub-wall 121a-2-1 and the sixth sub-wall 121a-2-2 along the direction B1 may also be greater than or equal to 0.3 and less than or equal to 3.

In one of the embodiments, a length component of the third side wall 121a-3 of the second overlapped part 121a2 along the direction A1 is equal to a length component of the fourth side wall 121a-4 of the second overlapped part 121a2 along the direction A1. One end of the third side wall 121a-3 is connected to the fifth sub-wall 121a-2-1, and the other end of the third side wall 121a-3 is connected to the sixth sub-wall 121a-2-2; one end of the fourth side wall 121a-4 is connected to the third sub-wall 121a-1-3, and the other end of the fourth side wall 121a-4 is connected to the fourth sub-wall 121a-1-4.

In this way, the designer achieves the purpose of reducing the difference in the color casts by optimizing pattern appearances of the first sub-patterns 1211 to reduce the difference in the color casts on the left side and the right side of the pixel G and the difference in the color casts on the upper side and the lower side of the pixel G without changing the pixel arrangement.

It may be understood that a ratio of the length component of the third side wall 121a-3 of the second overlapped part 121a2 along the direction A1 to the length component of the fourth side wall 121a-4 of the second overlapped part 121a2 along the direction A1 may be greater than or equal to 0.8 and less than or equal to 1.2. The ratio of the length component of the third side wall 121a-3 of the second overlapped part 121a2 along the direction A1 to the length component of the fourth side wall 121a-4 of the second overlapped part 121a2 along the direction A1 may also be greater than or equal to 0.3 and less than or equal to 3.

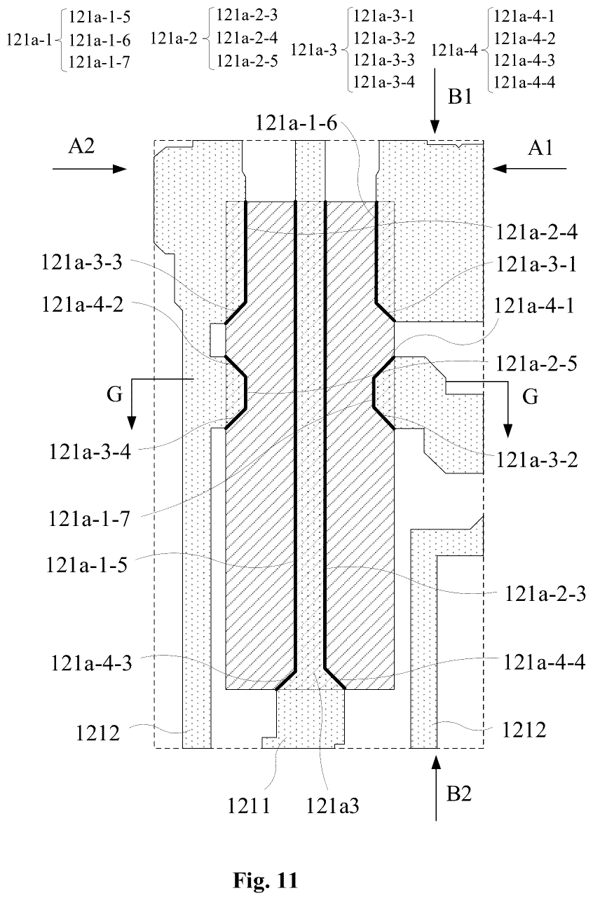

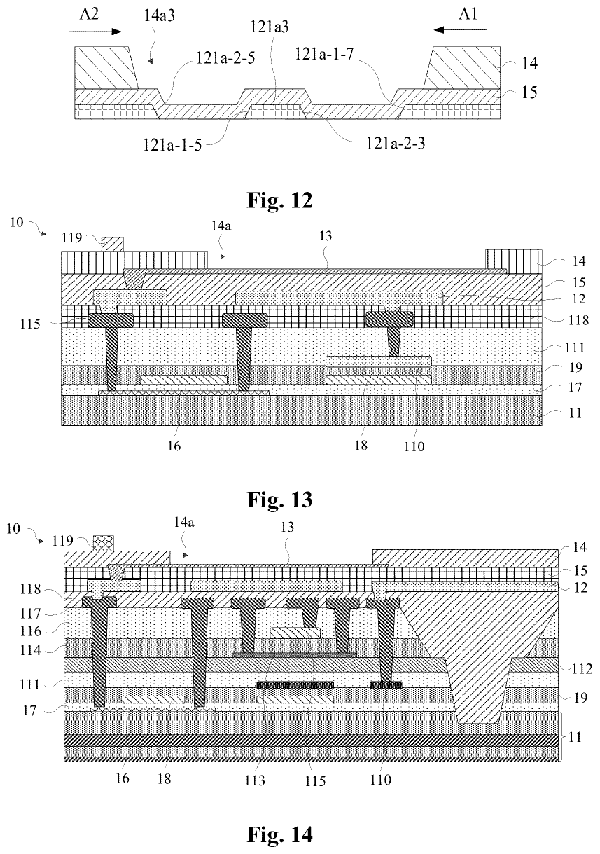

In one of the embodiments, as shown in FIG. 5, FIG. 11, and FIG. 12, the first pixel opening 14a includes a third sub-pixel opening 14a3. In an example, a pixel B corresponds to the third sub-pixel opening 14a3.

Specifically, an orthographic projection of the third sub-pixel opening 14a3 on the substrate 11 overlaps with orthographic projections of one corresponding first sub-pattern 1211 and two corresponding second sub-patterns 1212 on the substrate 11, and the overlapped part is a third sub-overlapped projection S1c. For example in FIG. 5, the big shaded pattern (rectangle) indicated by the line of the Pixel-B is equivalent to the orthographic projection of the third sub-pixel opening 14a3, and the small shaded graph indicated by the line of S1c is the third sub-overlapped projection S1c. A part of the first sub-pattern 1211 and parts of the second sub-patterns 1212 which correspond to the third sub-overlapped projection S1c are a third overlapped part 121a3, the first side wall 121a-1 of the third overlapped part 121a3 includes a seventh sub-wall 121a-1-5 located on the first sub-pattern 1211, and an eighth sub-wall 121a-1-6 and a ninth sub-wall 121a-1-7 located on one of the second sub-patterns 1212, and the eighth sub-wall 121a-1-6 and the ninth sub-wall 121a-1-7 are spaced apart from each other; the second side wall 121a-2 of the third overlapped part 121a3 includes a tenth sub-wall 121a-2-3 located on the first sub-pattern 1211, and an eleventh sub-wall 121a-2-4 and a twelfth sub-wall 121a-2-5 located on the other of the second sub-patterns 1212, and the eleventh sub-wall 121a-2-4 and the twelfth sub-wall 121a-2-5 are spaced apart from each other.

A sum of length components of the seventh sub-wall 121a-1-5, the eighth sub-wall 121a-1-6, and the ninth sub-wall 121a-1-7 along the direction B1 is equal to a sum of length components of the tenth sub-wall 121a-2-3, the eleventh sub-wall 121a-2-4, and the twelfth sub-wall 121a-2-5 along the direction B1.

Herein, side walls of the third overlapped part 121a3 facing the direction A1 are not continuous (that is, spaced apart from each other), and are the seventh sub-wall 121a-1-5, the eighth sub-wall 121a-1-6 and the ninth sub-wall 121a-1-7, respectively, and side walls of the third overlapped part 121a3 facing the direction A2 are not continuous (that is, spaced apart from each other), and are the tenth sub-wall 121a-2-3, the eleventh sub-wall 121a-2-4, and the twelfth sub-wall 121a-2-5, respectively. In the embodiments of the present application, the arrangement of the seventh sub-wall 121a-1-5, the eighth sub-wall 121a-1-6, the ninth sub-wall 121a-1-7, the tenth sub-wall 121a-2-3, the eleventh sub-wall 121a-2-4, and the twelfth sub-wall 121a-2-5 is optimized to make the sum of the length components of the seventh sub-wall 121a-1-5, the eighth sub-wall 121a-1-6, and the ninth sub-wall 121a-1-7 along the direction B1 equal to the sum of the length components of the tenth sub-wall 121a-2-3, the eleventh sub-wall 121a-2-4, and the twelfth sub-wall 121a-2-5 along the direction B1, so that the total length of the steps of the first electrodes 13 facing the direction B1 is as close to the total length of the steps of the first electrodes 13 facing the direction B2 as possible, and thus under a condition that the observer observes from the right side (corresponding to the direction A1) or from the left side (corresponding to the direction A2) under the large viewing angle, there is almost no difference in the color cast between the left side and the right side, thereby further improving the display effect.

It should be noted that, “equal” may mean “absolutely equal” or “approximately equal” herein. Under a condition that a ratio of the sum of the length components of the seventh sub-wall 121a-1-5, the eighth sub-wall 121a-1-6, and the ninth sub-wall 121a-1-7 along the direction B1 to the sum of the length components of the tenth sub-wall 121a-2-3, the eleventh sub-wall 121a-2-4, and the twelfth sub-wall 121a-2-5 along the direction B1 is equal to 1, the sum of the length components of the seventh sub-wall 121a-1-5, the eighth sub-wall 121a-1-6, and the ninth sub-wall 121a-1-7 along the direction B1 is absolutely equal to the sum of the length components of the tenth sub-wall 121a-2-3, the eleventh sub-wall 121a-2-4, and the twelfth sub-wall 121a-2-5 along the direction B1; and under a condition that the ratio of the sum of the length components of the seventh sub-wall 121a-1-5, the eighth sub-wall 121a-1-6, and the ninth sub-wall 121a-1-7 along the direction B1 to the sum of the length components of the tenth sub-wall 121a-2-3, the eleventh sub-wall 121a-2-4, and the twelfth sub-wall 121a-2-5 along the direction B1 is greater than or equal to 0.95 and less than or equal to 1.05, the sum of the length components of the seventh sub-wall 121a-1-5, the eighth sub-wall 121a-1-6, and the ninth sub-wall 121a-1-7 along the direction B1 is approximately equal to the sum of the length components of the tenth sub-wall 121a-2-3, the eleventh sub-wall 121a-2-4, and the twelfth sub-wall 121a-2-5 along the direction B1.

It may be understood that the ratio of the sum of the length components of the seventh sub-wall 121a-1-5, the eighth sub-wall 121a-1-6, and the ninth sub-wall 121a-1-7 along the direction B1 to the sum of the length components of the tenth sub-wall 121a-2-3, the eleventh sub-wall 121a-2-4, and the twelfth sub-wall 121a-2-5 along the direction B1 may also be greater than or equal to 0.8 and more and less than or equal to 1.2. The ratio of the sum of the length components of the seventh sub-wall 121a-1-5, the eighth sub-wall 121a-1-6, and the ninth sub-wall 121a-1-7 along the direction B1 to the sum of the length components of the tenth sub-wall 121a-2-3, the eleventh sub-wall 121a-2-4, and the twelfth sub-wall 121a-2-5 along the direction B1 may also be greater than or equal to 0.3 and less than or equal to 3.

In one of the embodiments, the third side wall 121a-3 of the third overlapped part 121a3 includes a thirteenth sub-wall 121a-3-1 and a fourteenth sub-wall 121a-3-2 located on one of the second sub-patterns 1212, and a fifteenth sub-wall 121a-3-3 and a sixteenth sub-wall 121a-3-4 located on the other of the second sub-patterns 1212, the thirteenth sub-wall 121a-3-1 and the fourteenth sub-wall 121a-3-2 are spaced apart from each other, and the fifteenth sub-wall 121a-3-3 and the sixteenth sub-wall 121a-3-4 are spaced apart from each other; the fourth side wall 121a-4 of the third overlapped part 121a3 includes a seventeenth sub-wall 121a-4-1 located on one of the second sub-patterns 1212, an eighteenth sub-wall 121a-4-2 located on the other of the second sub-patterns 1212, and a nineteenth sub-wall 121a-4-3 and a twentieth sub-wall 121a-4-4 located on the first sub-pattern 1211, and the nineteenth sub-wall 121a-4-3 and the twentieth sub-wall 121a-4-4 are spaced apart from each other.

A sum of length components of the thirteenth sub-wall 121a-3-1, the fourteenth sub-wall 121a-3-2, the fifteenth sub-wall 121a-3-3, and the sixteenth sub-wall 121a-3-4 along the direction A1 is equal to a sum of length components of the seventeenth sub-wall 121a-4-1, the eighteenth sub-wall 121a-4-2, the nineteenth sub-wall 121a-4-3, and the twentieth sub-wall 121a-4-4 along the direction A1.

Here, side walls of the third overlapped part 121a3 facing the direction B1 are not continuous (that is, spaced apart from each other), and are the thirteenth sub-wall 121a-3-1, the fourteenth sub-wall 121a-3-2, the fifteenth sub-wall 121a-3-3, and the sixteenth sub-wall 121a-3-4, respectively; side walls of the third overlapped part 121a3 facing the direction B2 are not continuous (that is, spaced apart from each other), and are the seventeenth sub-wall 121a-4-1, the eighteenth sub-wall 121a-4-2, the nineteenth sub-wall 121a-4-3, and the twentieth sub-wall 121a-4-4. In the embodiments of the present application, the arrangement of the above side walls is optimized to make the sum of the length components of the thirteenth sub-wall 121a-3-1, the fourteenth sub-wall 121a-3-2, the fifteenth sub-wall 121a-3-3, and the sixteenth sub-wall 121a-3-4 along the direction A1 equal to the sum of the length components of the seventeenth sub-wall 121a-4-1, the eighteenth sub-wall 121a-4-2, the nineteenth sub-wall 121a-4-3, and the twentieth sub-wall 121a-4-4 along the direction A1, so that the total length of the steps of the first electrodes 13 facing the direction B1 is as close to the total length of the steps of the first electrodes 13 facing the direction B2 as possible, and thus under a condition that the observer observes from the upper side (corresponding to the direction B1) or from the lower side (corresponding to the direction B2) under the large viewing angle, there is almost no difference in the color cast between the left side and the right side, thereby further improving the display effect.

It should be noted that, “equal” may mean “absolutely equal” or “approximately equal” herein. Under a condition that a ratio of the sum of the length components of the thirteenth sub-wall 121a-3-1, the fourteenth sub-wall 121a-3-2, the fifteenth sub-wall 121a-3-3, and the sixteenth sub-wall 121a-3-4 along the direction A1 to the sum of the length components of the seventeenth sub-wall 121a-4-1, the eighteenth sub-wall 121a-4-2, the nineteenth sub-wall 121a-4-3, and the twentieth sub-wall 121a-4-4 along the direction A1 is equal to 1, the sum of the length components of the thirteenth sub-wall 121a-3-1, the fourteenth sub-wall 121a-3-2, the fifteenth sub-wall 121a-3-3, and the sixteenth sub-wall 121a-3-4 along the direction A1 is absolutely equal to the sum of the length components of the seventeenth sub-wall 121a-4-1, the eighteenth sub-wall 121a-4-2, the nineteenth sub-wall 121a-4-3, and the twentieth sub-wall 121a-4-4 along the direction A1; under a condition that the ratio of the sum of the length components of the thirteenth sub-wall 121a-3-1, the fourteenth sub-wall 121a-3-2, the fifteenth sub-wall 121a-3-3, and the sixteenth sub-wall 121a-3-4 along the direction A1 to the sum of the length components of the seventeenth sub-wall 121a-4-1, the eighteenth sub-wall 121a-4-2, the nineteenth sub-wall 121a-4-3, and the twentieth sub-wall 121a-4-4 along the direction A1 is greater than or equal to 0.95 and less than or equal to 1.05, the sum of the length components of the thirteenth sub-wall 121a-3-1, the fourteenth sub-wall 121a-3-2, the fifteenth sub-wall 121a-3-3, and the sixteenth sub-wall 121a-3-4 along the direction A1 is approximately equal to the sum of the length components of the seventeenth sub-wall 121a-4-1, the eighteenth sub-wall 121a-4-2, the nineteenth sub-wall 121a-4-3, and the twentieth sub-wall 121a-4-4 along the direction A1.

In one of the embodiments, the seventh sub-wall 121a-1-5 is connected to the nineteenth sub-wall 121a-4-3, the eighth sub-wall 121a-1-6 is connected to the thirteenth sub-wall 121a-3-1, one end of the ninth sub-wall 121a-1-7 is connected to the fourteenth sub-wall 121a-3-2, the other end of the ninth sub-wall 121a-1-7 is connected to the seventeenth sub-wall 121a-4-1, the tenth sub-wall 121a-2-3 is connected to the twentieth sub-wall 121a-4-4, the eleventh sub-wall 121a-2-4 is connected to the fifteenth sub-wall 121a-3-3, one end of the twelfth sub-wall 121a-2-5 is connected to the sixteenth sub-wall 121a-3-4, and the other end of the twelfth sub-wall 121a-2-5 is connected to the eighteenth sub-wall 121a-4-2.

In this way, the designer achieves the purpose of reducing the difference in the color casts by optimizing pattern appearances of the first sub-patterns 1211 and the second sub-patterns 1212 to reduce the difference in the color casts on the left side and the right side of the pixel B and the difference in the color casts on the upper side and the lower side of the pixel B without changing the pixel arrangement.

In one of the embodiments, the first overlapped projection S1 is asymmetrical in shape, that is, the overlapped part 121a is an asymmetrical structure. In this way, the difference in the color casts under the large viewing angle may be improved under a condition that the overlapped part 121a is the asymmetrical structure.

In one of the embodiments, the display panel 10 further includes a first insulation layer 15 provided between the first metal layer 12 and the first electrode 13. A side of the first metal layer 12 adjacent to the first insulation layer 15 is in contact with the first insulation layer 15, and a side of the first electrode 13 adjacent to the first insulation layer 15 is in contact with the first insulation layer 15.

The inventor has found that a metal pattern located under the first electrode 13 and closest to the first electrode 13 has a relatively big effect on the color casts. In the embodiments of the present application, a pattern appearance of the metal layer closest to the first electrode 13 is optimized, which may reduce the difference in the color casts to the greatest extent.

In one of the embodiments, the first insulation layer 15 is a planarization film layer. It should be noted that, even if the first insulation layer 15 is the planarization film layer, the first electrode 13 located above the first metal pattern 121 has a step.

It may be understood that sub-pixels in the display panel 10 are electrically connected to a pixel driving circuit that drives the sub-pixels to emit light.

In one of the embodiments, as shown in FIG. 13, the display panel 10 further includes a semiconductor layer 16, a second insulation layer 17, a second metal layer 18, a third insulation layer 19, a third metal layer 110, a fourth insulation layer 111, a fourth metal layer 115, and a first planarization layer 118 that are stacked in sequence on the substrate 11. The first metal layer 12 is provided on a side of the first planarization layer 118 away from the substrate 11.

In one of the embodiments, as shown in FIG. 14, the display panel 10 further includes a semiconductor layer 16, a second insulation layer 17, a second metal layer 18, a third insulation layer 19, a third metal layer 110, a fourth insulation layer 111, a fifth insulation layer 112, an oxide metal layer 113, a sixth insulation layer 114, a fourth metal layer 115, a seventh insulation layer 116, a fifth metal layer 117, and a first planarization layer 118 that are stacked in sequence on the substrate 11. The first metal layer 12 is provided on a side of the first planarization layer 118 away from the substrate 11. It may be understood that the substrate 11 may be a stacked structure formed by a plurality of film layer structures.

In one of the embodiments, the display panel 10 further includes a support column 119 provided on a side of the pixel definition layer 14 away from the substrate 11, and the support column 119 is used for supporting a mask plate.

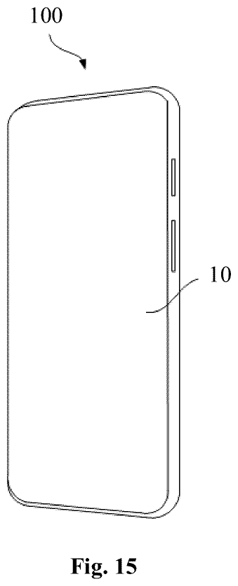

In a second aspect, as shown in FIG. 15, based on the same inventive concept, the embodiments of the present application provide a display device 100 including the display panel 10 in any one of the embodiments of the first aspect.

The display device 100 may be a notebook computer, a mobile phone, a wireless device, a personal digital assistant (PDA), a hand-held or portable computer, a GPS receiver/navigator, a camera, an MP4 video player, a video camera, a game console, a watch, a clock, a calculator, a television monitor, a flat panel display, a computer monitor, an automotive display (such as an odometer display), a navigator, a cabin controller and/or display, a display of a camera view (such as a display of a rear view camera in a vehicle), an electronic photograph, an electronic billboard or sign, a projector, a package, and the like.

In the display device 100 according to the embodiments of the present application, a ratio of a length component of the first side wall 121a-1 along the direction B1 of an overlapped part (same as the above overlapped part 121a) of the first metal pattern 121 and the first pixel opening 14a along the direction A1 to a length component of the second side wall 121a-2 along the direction B1 of an overlapped part of the first metal pattern 121 and the first pixel opening 14a along the direction A2 is greater than or equal to 0.3 and less than or equal to 3, so that a difference in magnitude of the length components of the first side wall 121a-1 and the second side wall 121a-2 along the direction B1 is not very big, and under a condition that the observer observes from the right side (corresponding to the direction A1) or from the left side (corresponding to the direction A2) under the large viewing angle, the difference in the color casts of the left side and the right side is not very big, thereby improving the display effect.

The technical features of the above embodiments can be combined in any way, and in order to make the description clear, not all the possible combinations of the technical features in the above embodiments are described. However, as long as there is no contradiction among the combinations of these technical features, they should be considered as the scope that the specification recites.

The embodiments described above represent only a few embodiments of the present application and description thereof is relatively specific and detailed, but are not to be construed as limiting the patent scope of the present invention. It should be noted that a person skilled in the art could also make several changes and modifications without departing from the concept of the present application, which falls within the scope of protection of this application. Therefore, the protection scope of the present application should be subject to the appended claims.

What is claimed is:

1. A display panel comprising:
a substrate;
a first metal layer located on a side of the substrate and comprising a first metal pattern;
a first electrode located on a side of the substrate; and
a pixel definition layer located on a side of the first electrode away from the substrate and comprising a first pixel opening corresponding to the first electrode; and an outer contour of an orthographic projection of the first electrode on the substrate being located outside an outer contour of an orthographic projection of the corresponding first pixel openings on the substrate;
wherein an overlapped part of an orthographic projection of the first metal pattern on the substrate and the orthographic projection of the first pixel opening on the substrate is a first overlapped projection; a part of the one of the first metal patterns corresponding to the first overlapped projection is an overlapped part; the overlapped part comprises a first side wall facing a direction A1 and a second side wall facing a direction A2 opposite and parallel to the direction A1;
a ratio of a length component of the first side wall along a direction B1 intersecting with the direction A1 to a length component of the second side wall along the direction B1 is greater than or equal to 0.3 and less than or equal to 3.

2. The display panel according to claim 1, wherein the ratio of the length component of the first side wall along the direction B1 to the length component of the second side wall along the direction B1 is greater than or equal to 0.8 and less than or equal to 1.2.

3. The display panel according to claim 2, wherein the length component of the first side wall along the direction B1 is equal to the length component of the second side wall along the direction B1.

4. The display panel according to claim 1, wherein in the overlapped part and the first pixel opening corresponding to the overlapped part,
a distance between the first side wall of the overlapped part and an edge of a side of the first pixel opening close to the first side wall is greater than 0 μm; and/or, a distance between the second side wall of the overlapped part and an edge of a side of the first pixel opening close to the second side wall is greater than 0 μm.

5. The display panel according to claim 4, wherein in the overlapped part and the first pixel opening corresponding to the overlapped part,
the distance between the first side wall of the overlapped part and the edge of the side of the first pixel opening close to the first side wall is greater than or equal to 1 μm; and/or, the distance between the second side wall of the overlapped part and the edge of the side of the first pixel opening close to the second side wall is greater than or equal to 1 μm.

6. The display panel according to claim 1, wherein the overlapped part comprises a third side wall facing the direction B1 and a fourth side wall facing a direction B2 opposite and parallel to the direction B1; and
a ratio of a length component of the third side wall along the direction A1 to a length component of the fourth side wall along the direction A1 is greater than or equal to 0.3 and less than or equal to 3.

7. The display panel according to claim 6, wherein the ratio of the length component of the third side wall along the direction A1 to the length component of the fourth side wall along the direction A1 is greater than or equal to is 0.8 and less than or equal to 1.2.

8. The display panel according to claim 7, wherein the length component of the third side wall along the direction A1 is equal to the length component of the fourth side wall along direction the A1.

9. The display panel according to claim 6, wherein in the overlapped part and the first pixel opening corresponding to the overlapped part,
a distance between the third side wall of the overlapped part and an edge of a side of the first pixel opening close to the third side wall is greater than 0 μm; and/or, a distance between the fourth side wall of the overlapped part and an edge of a side of the first pixel opening close to the fourth side wall is greater than 0 μm.

10. The display panel according to claim 9, wherein in the overlapped part and the first pixel opening corresponding to the overlapped part,
the distance between the third side wall of the overlapped part and the edge of the side of the first pixel opening close to the third side wall is greater than or equal to 1 μm; and/or, the distance between the fourth side wall of the overlapped part and the edge of the side of the first pixel opening close to the fourth side wall is greater than or equal to 1 μm.

11. The display panel according to claim 6, wherein the first metal pattern comprises a plurality of first sub-patterns and a plurality of second sub-patterns which are arranged alternately and configured to transmit different electrical signals, respectively; and
an orthographic projection of at least one of the plurality of first sub-patterns or the plurality of second sub-patterns on the substrate overlaps with the orthographic projection of the first pixel opening on the substrate.

12. The display panel according to claim 11, wherein the first pixel opening comprises a first sub-pixel opening;
an orthographic projection of the first sub-pixel opening on the substrate overlaps with an orthographic projection of a corresponding one of the plurality of first sub-patterns on the substrate, an overlapped part of the orthographic projection of the first sub-pixel opening on the substrate and the orthographic projection of the corresponding one of the plurality of first sub-patterns on the substrate is a first sub-overlapped projection; a part of the corresponding one of the plurality of first sub-patterns corresponding to the first sub-overlapped projection is a first overlapped part, the first side wall of the first overlapped part comprises a first sub-wall and a second sub-wall which are spaced apart from each other, and a sum of length components of the first sub-wall and the second sub-wall along the direction B1 is equal to the length component of the second side wall of the first overlapped part along the direction B1.

13. The display panel according to claim 12, wherein a length component of the third side wall of the first overlapped part along the direction A1 is equal to the length component of the fourth side wall of the first overlapped part along the direction A1;
one end of the third side wall is connected to the first sub-wall, and the other end of the third side wall is connected to the second sub-wall; and the fourth side wall is located between the second sub-wall and the second side wall.

14. The display panel according to claim 11, wherein the first pixel opening comprises a second sub-pixel opening;
an orthographic projection of the second sub-pixel opening on the substrate overlaps with an orthographic projection of a corresponding one of the plurality of first sub-patterns on the substrate, an overlapped part of the orthographic projection of the second sub-pixel opening on the substrate and the orthographic projection of the corresponding one of the plurality of first sub-patterns on the substrate is a second sub-overlapped projection; a part of the corresponding one of the plurality of first sub-patterns corresponding to the second sub-overlapped projection is a second overlapped part, the first side wall of the second overlapped part comprises a third sub-wall and a fourth sub-wall which are spaced apart from each other, and the second side wall of the second overlapped part comprises a fifth sub-wall and a sixth sub-wall which are spaced apart from each other; and
a sum of length components of the third sub-wall and the fourth sub-wall along the direction B1 is equal to a sum of length components of the fifth sub-wall and the sixth sub-wall along the direction B1.

15. The display panel according to claim 14, wherein a length component of the third side wall of the second overlapped part along the direction A1 is equal to a length component of the fourth side wall of the second overlapped part along the direction A1;
one end of the third side wall is connected to the fifth sub-wall, and the other end of the third side wall is connected to the sixth sub-wall; and one end of the fourth side wall is connected to the third sub-wall, and the other end of the fourth side wall is connected to the fourth sub-wall.

16. The display panel according to claim 11, wherein the first pixel opening comprises a third sub-pixel opening;
an orthographic projection of the third sub-pixel opening on the substrate overlaps with orthographic projections of a corresponding one of the plurality of first sub-patterns and corresponding two of the plurality of second sub-patterns on the substrate, an overlapped part of the orthographic projection of the third sub-pixel opening on the substrate and the orthographic projections of the corresponding one of the plurality of first sub-patterns and the corresponding two of the plurality of second sub-patterns on the substrate is a third sub-overlapped projection;
a part of the corresponding one of the plurality of first sub-patterns corresponding to the third sub-overlapped projection and parts of the corresponding two of the plurality of the second sub-patterns corresponding to the third sub-overlapped projection form a third overlapped part, the first side wall of the third overlapped part comprises a seventh sub-wall located on the corresponding one of the plurality of first sub-patterns, and an eighth sub-wall and a ninth sub-wall located on one of the corresponding two of the plurality of second sub-patterns, the eighth sub-wall and the ninth sub-wall being spaced apart from each other; the second side wall of the third overlapped part comprises a tenth sub-wall located on the corresponding one of the plurality of first sub-patterns, and an eleventh sub-wall and a twelfth sub-wall located on the other of the corresponding two of the plurality of second sub-patterns, the eleventh sub-wall and the twelfth sub-wall being spaced apart from each other; and
a sum of length components of the seventh sub-wall, the eighth sub-wall and the ninth sub-wall along the direction B1 is equal to a sum of length components of the tenth sub-wall, the eleventh sub-wall and the twelfth sub-wall along the direction B1.

17. The display panel according to claim 16, wherein the third side wall of the third overlapped part comprises a thirteenth sub-wall and a fourteenth sub-wall located on one of the corresponding two of the plurality of second sub-patterns, and a fifteenth sub-wall and a sixteenth sub-wall located on the other of the corresponding two of the plurality of second sub-patterns, the thirteenth sub-wall and the fourteenth sub-wall being spaced apart from each other, and the fifteenth sub-wall and the sixteenth sub-wall being spaced apart from each other;
the fourth side wall of the third overlapped part comprises a seventeenth sub-wall located on one of the corresponding two of the plurality of second sub-patterns, an eighteenth sub-wall located on the other of the corresponding two of the plurality of second sub-patterns, and a nineteenth sub-wall and a twentieth sub-wall located on the corresponding one of the plurality of first sub-patterns, the nineteenth sub-wall and the twentieth sub-wall being spaced apart from each other; and
a sum of length components of the thirteenth sub-wall, the fourteenth sub-wall, the fifteenth sub-wall, and the sixteenth sub-wall along the direction A1 is equal to a sum of length components of the seventeenth sub-wall, the eighteenth sub-wall, the nineteenth sub-wall, and the twentieth sub-wall along the direction A1.

18. The display panel according to claim 17, wherein the seventh sub-wall is connected to the nineteenth sub-wall, the eighth sub-wall is connected to the thirteenth sub-wall, one end of the ninth sub-wall is connected to the fourteenth sub-wall, the other end of the ninth sub-wall is connected to the seventeenth sub-wall, the tenth sub-wall is connected to the twentieth sub-wall, the eleventh sub-wall is connected to the fifteenth sub-wall, one end of the twelfth sub-wall is connected to the sixteenth sub-wall, and the other end of the twelfth sub-wall is connected to the eighteenth sub-wall.

19. The display panel according to claim 11, wherein the plurality of first sub-patterns are each configured to transmit a power signal, and the plurality of second sub-patterns are each configured to transmit a data signal.

20. A display panel according to claim 1, wherein the first overlapped projection is asymmetrical in shape.

21. The display panel according to claim 1, wherein the display panel further comprises a first insulation layer provided between the first metal layer and the first electrode; and
a side of the first metal layer adjacent to the first insulation layer is in contact with the first insulation layer, and a side of the first electrode adjacent to the first insulation layer is in contact with the first insulation layer.

22. A display device comprising the display panel comprising:
a substrate;
a first metal layer located on a side of the substrate and comprising a first metal pattern;
a first electrode located on a side of the substrate; and
a pixel definition layer located on a side of the first electrode away from the substrate and comprising a first pixel opening corresponding to the first electrode; and an outer contour of an orthographic projection of the first electrode on the substrate being located outside an outer contour of an orthographic projection of the corresponding first pixel openings on the substrate;
wherein an overlapped part of an orthographic projection of the first metal pattern on the substrate and the orthographic projection of the first pixel opening on the substrate is a first overlapped projection; a part of the one of the first metal patterns corresponding to the first overlapped projection is an overlapped part; the overlapped part comprises a first side wall facing a direction A1 and a second side wall facing a direction A2 opposite and parallel to the direction A1;
a ratio of a length component of the first side wall along a direction B1 intersecting with the direction A1 to a length component of the second side wall along the direction B1 is greater than or equal to 0.3 and less than or equal to 3.
